(19) United States
(12) Patent Application Publication
(10) Pub. No.: US 2007/0227707 A1
(43) Pub. Date: Oct. 4, 2007

(54) Method, apparatus and system for providing for optimized heat exchanger fin spacing

(76) Inventors: Sridhar V. Machiroutu, Fremont, CA (US); Himanshu Pokharna, San Jose, CA (US); Rajiv K. Mongia, Fremont, CA (US); Eric Baugh, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/395,352

(22) Filed: Mar. 31, 2006

(51) Int. Cl. H05K 7/20

(52) U.S. Cl. 165/121; 165/80.4; 165/80.3

(57) ABSTRACT

A method, apparatus and system are described for providing for optimized heat exchanger fin spacing. The system may include a chassis and an apparatus. The apparatus may include a heat exchanger, and a cold plate. In some embodiments, a pump may provide for the flow of the fluid between the heat exchanger and the cold plate. In some embodiments, the heat exchanger may include a tube to transport a cooling fluid, and a plurality of fins coupled to the tube and having a spacing that facilitates optimizing the airflow from a blower; and a cold plate coupled to the tube and coupled to an electronic component from which thermal energy is transferred. Other embodiments may be described.

### BACKGROUND

1. Technical Field

Some embodiments of the present invention generally relate to cooling systems. More specifically, some embodiments relate to an apparatus, system and method for optimizing the pressure profile of a heat exchanger that operates with a blower.

2. Discussion

In recent years, developments in electronic components, such as processors with or without multiple cores, or chipsets, have been made to meet increasing demands for better performance and reduced size. Thus, these demands have led to a decrease in the size and an increase in the density of components. These factors lead to increases in heat generation. Particularly in mobile computing environments, these factors can lead to overheating, which may negatively affect performance, and can significantly reduce battery life.

The above-mentioned factors increase the need for effective cooling for electronic systems. Two types of cooling are generally implemented, either alone, but often in combination: air and liquid. In air cooling, a blower, typically a fan, moves air over a heat exchanger's surface. In liquid cooling, a heat exchanger may be implemented to remove heat from the liquid, which indirectly removes heat from the electronic components. Pumped loops have been proposed for achieving higher heat dissipation rates at a hot spot, such as an electronic component. FIG. 1 illustrates a conventional cooling system configuration at the heat exchanger.

In FIG. 1, a heat exchanger system 100 of conventional design shows a blower 110 residing within proximity to a heat exchanger 106. The heat exchanger 106 includes a plurality of fins 108. The blower 110 produces a pressure profile 150 at the heat exchanger 106. The plurality of fins 108 allows the airflow to pass through the fins. A resulting pressure profile 152 is measurable as the airflow exits the heat exchanger 106.

As FIG. 1 illustrates the pressure profile is not uniform and the heat exchanger does not provide as high of a level of performance as it could.

Therefore, there is a need for alternative heat exchanger systems for systems, such as computer systems. In particular, there is a need for cooling systems that, at least, enhance heat exchanger performance.

### BRIEF DESCRIPTION OF THE DRAWINGS

Various advantages of embodiments of the present invention will become apparent to one of ordinary skill in the art by reading the following specification and appended claims, and by referencing the following drawings, in which:

FIG. 1 is an illustrative example of a conventional design of a heat exchanger system;

FIG. 2 is an illustrative example of a heat exchanger system according to some embodiments of the invention;

FIG. 3A is a cross-sectional diagram of a cooling apparatus with heat exchanger according to some embodiments of the invention;

FIG. 3B is a cross-sectional diagram of a cooling apparatus with a condenser-style heat exchanger according to some embodiments of the invention;

FIG. 4 is a cross-sectional diagram of a system, such as a computer system, with a cooling apparatus according to some embodiments of the invention;

FIG. 5 includes cross-sectional diagrams of various examples of heat exchanger fin shapes according to some embodiments of the invention; and

FIG. 6 shows a flow diagram of the optimized heat exchanger fin spacing process according to some embodiments of the invention.

### DETAILED DESCRIPTION OF SOME EMBODIMENTS

Reference is made to some embodiments of the invention, examples of which are illustrated in the accompanying drawings. While the present invention will be described in conjunction with the embodiments, it will be understood that they are not intended to limit the invention to these embodiments. On the contrary, the invention is intended to cover alternatives, modifications and equivalents, which may be included within the spirit and scope of the invention as defined by the appended claims. Moreover, in the following detailed description of the invention, numerous specific details are set forth in order to provide a thorough understanding of the invention. However, the invention may be practiced without these specific details. In other instances, well-known methods, procedures, components and circuits have not been described in detail as not to unnecessarily obscure aspects of the invention.

Some embodiments of the invention are directed to a method, apparatus and system for optimized heat exchanger fin spacing. Some embodiments of the system may include a chassis and an apparatus. In some embodiments of the invention, the apparatus may include a heat exchanger, and a cold plate. In some embodiments, a pump may provide for the flow of the fluid between the heat exchanger and the cold plate. In some embodiments, the heat exchanger may include a tube to transport a cooling fluid, and a plurality of fins coupled to the tube and having a spacing that facilitates optimizing the airflow from a blower; and a cold plate coupled to the tube and coupled to an electronic component from which thermal energy is transferred.

According to some embodiments, the heat pipe may thermally couple the cold plate to the heat exchanger. According to some embodiments of the invention, the heat exchanger includes a thermally conductive tube, which may be molded into a series of thermally conductive fins and integral mounting features. The conduit of tubing may, for example, be thermally conductive metal tube. However, other type of suitable material that allows the fluids, such as, but not limited to, hot liquid, air or cooling agent to flow through may also be used.

Reference in the specification to “one embodiment” or “some embodiments” of the invention means that a particular feature, structure or characteristic described in connection with the embodiment is included in at least one embodiment of the invention. Thus, the appearances of the phrase “in some embodiments” or “according to some embodiments” appearing in various places throughout the specification are not necessarily all referring to the same embodiment.

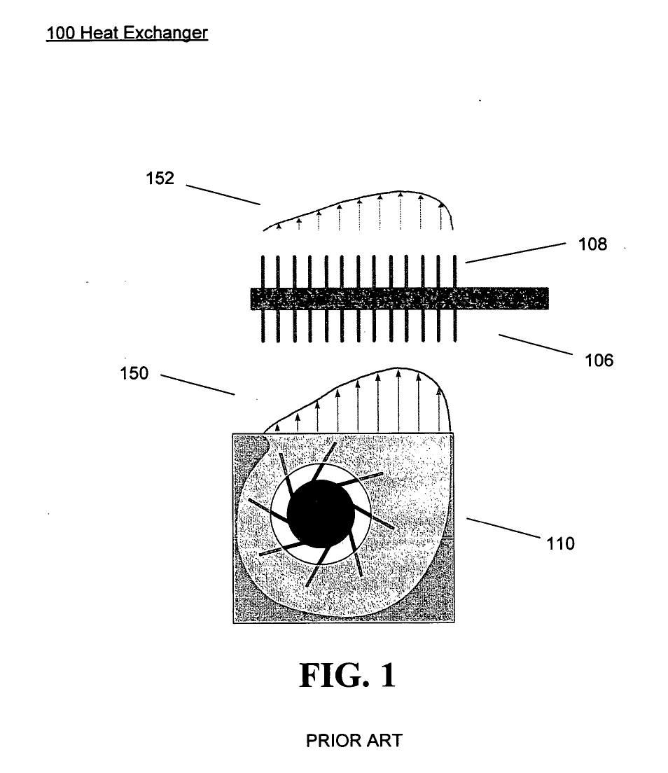

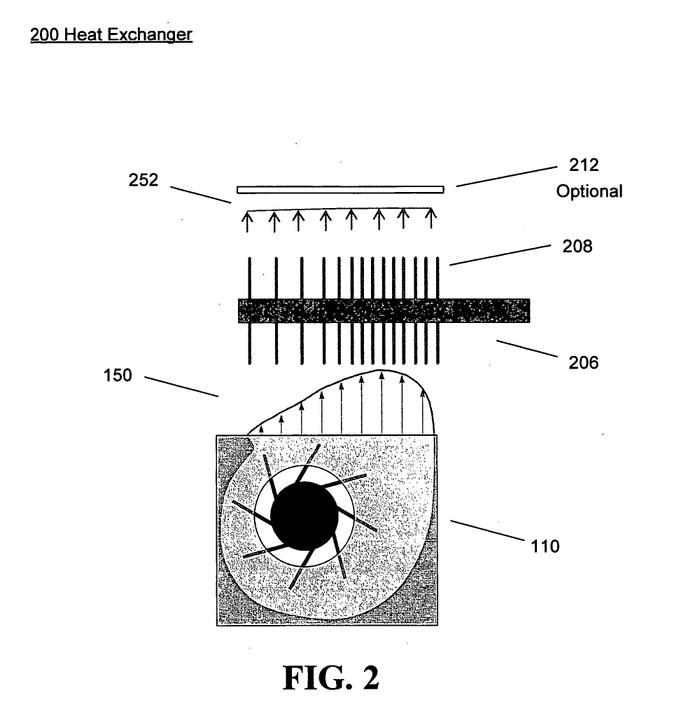

In some embodiments, the heat exchanger (HX) which may be used in conjunction with a blower, such as, but not limited to a centrifugal blower fan or axial flow fan, in system cooling generally has uniformly spaced fins, as described with respect to FIG. 1. As a person of ordinary skill in the relevant art would appreciate, the spacing of the fins is determined by the desire to provide maximum airflow without excessive flow blockage. However, the pressure and velocity profiles of the typical blower are far from uniform, as represented in FIG. 1. According to some embodiments of the invention, the spacing of the fins may be altered to make them narrower where the velocity is the greatest and wider where the velocity is least, as shown in FIG. 2, described below. In some embodiments, the overall heat transfer coefficient of the HX may be maintained at a practical value while reducing the pressure loss across it. This has the benefit of increasing the apparatus and system airflow.

According to some embodiments, the total pressure at the exit of the blower, where the pressure profile may be non-uniform. The heat exchanger fin spacing may be designed such that the effective pressure drop in each fin gap matches the non-uniform total pressure at the blower fan exit.

As the thermal designs may be frequently limited by the amount of airflow the available blower can provide given the system resistance it encounters, embodiments of this invention may provide a means to improve the airflow while maintaining an effective HX. As such, by designing the heat exchanger fin gaps non-uniformly to match the total pressure profile at the exit of the fan, the effective heat exchanger performance may be enhanced. In some embodiments, an alternative way to look at this is that a smaller heat exchanger with lower effective pressure drop may be needed to maintain a desired level of performance when the heat exchanger design incorporates non-uniform fin gaps.

In FIG. 2, a heat exchanger system 200 of some embodiments shows a blower 110 residing within proximity to a heat exchanger 206. The heat exchanger 206 includes a plurality of fins 208. As described above, the spacing between each of the fins has been adjusted to match the profile of the blower 110. The blower 110 produces a pressure profile 150 at the heat exchanger 206. The plurality of fins 208 allows the airflow to pass through the fins. A resulting pressure profile 252 is measurable as the airflow exits the heat exchanger 206, and in some embodiments, provides a nearly uniform pressure profile, as illustrated.

In some embodiments, a profile sensor 212 may be coupled to the opposite side of the heat exchanger 206 to determine either the pressure profile and/or the velocity profile. In some embodiments, the profile sensor 212 may be a MEMS pressure sensor array, a hot wire anemometer or equivalent sensor as one of ordinary skill in the relevant art would appreciate based at least on the teachings provided herein. According to some embodiments of the invention, the profile sensor 212 may allow for the adjustment of the fin spacing if or when non-uniformities in the profile are detected. In such embodiments, the profile sensor 212 may be coupled to other logic (not shown) capable of registering the non-uniformity and making adjustments to the fin spacing to compensate.

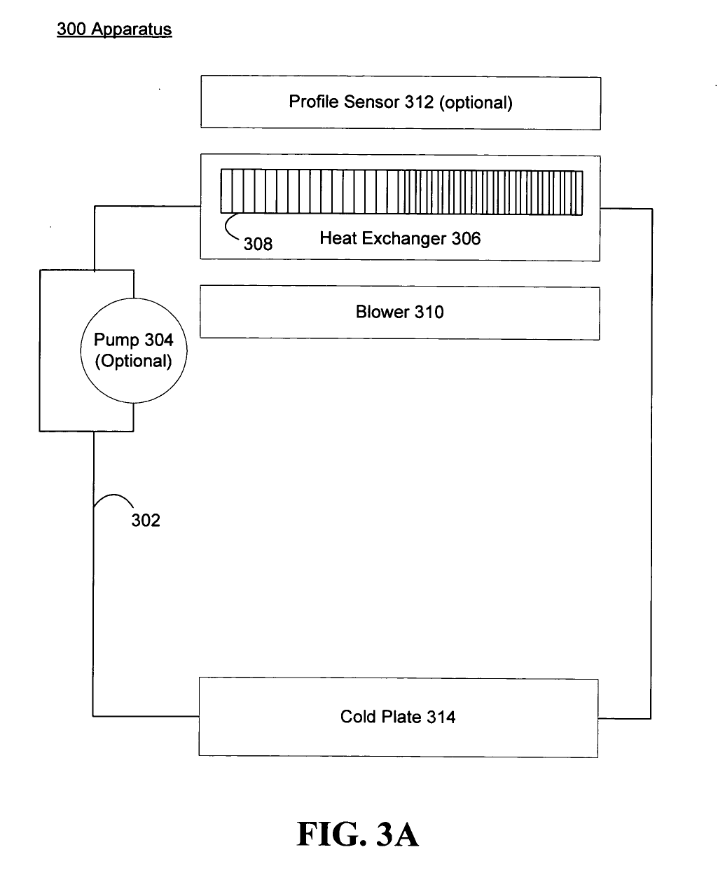

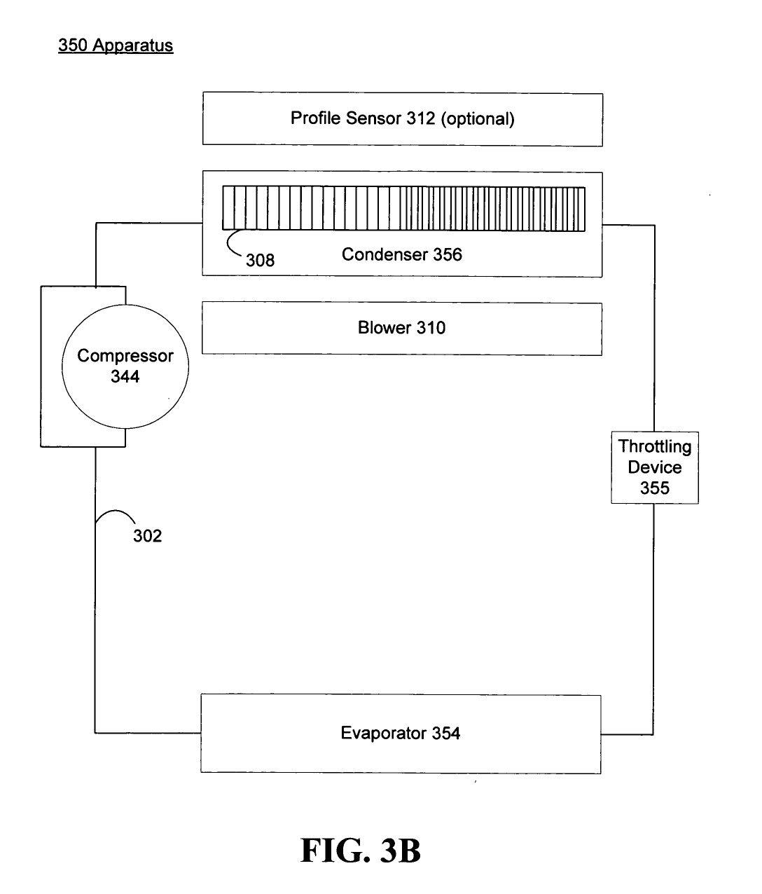

FIG. 3A is a cross-sectional diagram of a cooling apparatus 300 with heat exchanger according to some embodiments of the invention. In FIG. 3, the cooling apparatus 300 of some embodiments includes a heat exchanger 306, where the heat exchanger 306 includes a plurality of fins 308. In some embodiments, the spacing of the fins is non-uniform. The apparatus 300 may include a cold plate 314 which may be thermally coupled to an electronic component when in a system. Tubing 302 may provide for the flow of a liquid or cooling fluid from the cold plate 314 to the heat exchanger 306. The heat exchanger 306 may serve to transfer heat from the liquid flowing through the tubing 302.

In some embodiments, the apparatus 300 may include a blower 310. The blower 310 may be exposed to ambient air, and may be a axial flow fan, or a centrifugal blower fan, or another type of fan or fans, as one of ordinary skill in the relevant art would appreciate based at least on the teachings provided herein. Moreover, one of ordinary skill in the relevant art would appreciate how to implement the use of the fan in the apparatus 300, based at least on the teachings provided herein. A pump 304, powered by a battery or other power supply, may push the liquid through the tubing 302.

In embodiments of the invention, the tubing 302 may be flexible or rigid. It is noted that even a somewhat (or less than completely) flexible tubing may be preferably used to connect cold plate 314 and the pump 304 to the heat exchanger 306 because a flexible tubing may be easily routed around other components inside a system, such as, but not limited to a computer system, in which some embodiments of the apparatus 300 may operate and accommodate a greater number of system designs.

In some embodiments, a profile sensor 312 may be coupled opposite the heat exchanger 306. The sensor 312 may measure the pressure or velocity profile as the air flow leaves the heat exchanger 306. In the event that the profile is non-uniform, the sensor may provide the profile to other logic of the apparatus (not shown). The logic may make adjustments to the fin spacing of the plurality of fins 308, such as to provide a uniform profile. One of ordinary skill in the relevant arts would appreciate the form of such logic and the mechanisms for the adjustment of the fin spacing, as is described herein with respect to various embodiments of the invention.

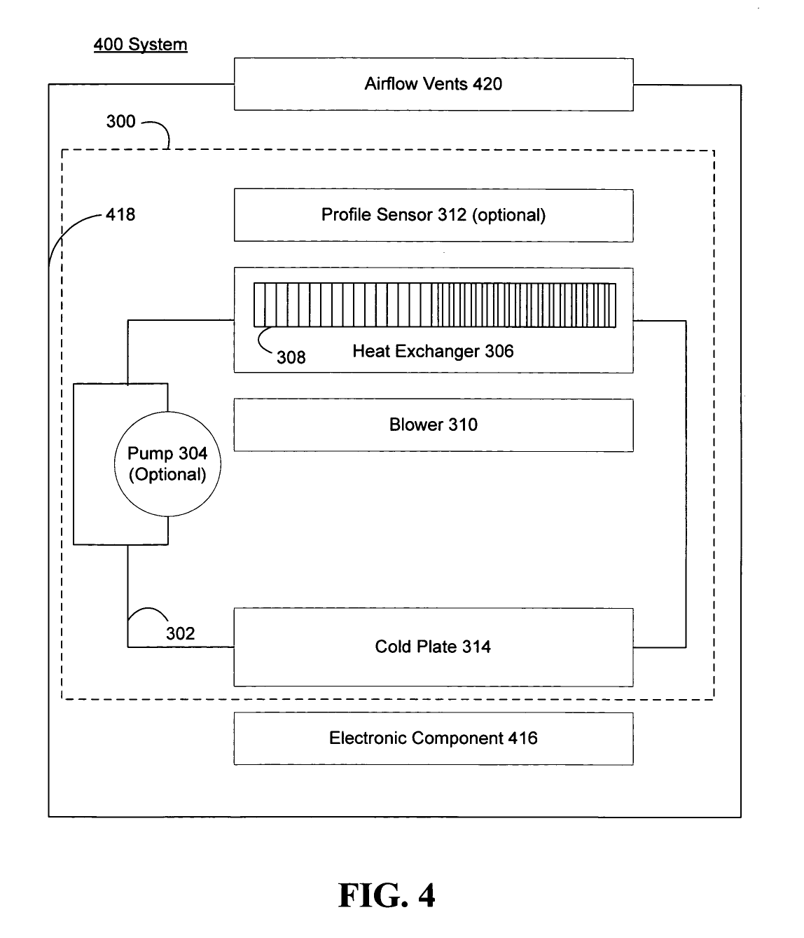

According to some embodiments of the invention, a cold plate 314 may provide for the transfer of a substantial amount of the thermal energy generated by one or more electronic components (see FIG. 4), and to be transferred to the heat exchanger 306. Furthermore, in some embodiments of the invention, the cold plate or a cold plate that includes a manifold plate (not shown) may be replaced with other types of heat sink(s). According to some embodiments of the invention, the cold plate 314 may be a thermally conductive block on which the electronic component may either directly mount or may be closely positioned for heat removal. In some embodiments, the thermally conductive block may be in the shape of a plate with one or more groove(s), a channel(s) or a thermally conductive tube(s) running through it.

According to some embodiments of the invention, the fluid in the tubing 302 may be a liquid coolant, such as a distilled water, ethylene/propylene, or glycol mixture. Other types of liquid coolant, such as water or water with mixture of ions, may also be used, as long as they serve the function of cooling, as one of ordinary skill in the relevant art would appreciate based at least on the teachings provided herein.

Alternative types of tubing, such as heat pipes may be employed by some embodiments of the invention, and the above description is not intended to limit the scope of the embodiments. One of ordinary skill in the art would appreciate that heat pipes may be used, in accordance with some embodiments of the invention, based at least on the teachings provided herein.

FIG. 3B is a cross-sectional diagram of a cooling apparatus 350 with a condenser-style heat exchanger 356 according to some embodiments of the invention. As one of ordinary skill in the relevant art(s) would appreciate, based at least on the teachings contained herein, the heat exchanger 356 may include the non-uniform fins 308 and operate as a refrigeration-style cooling apparatus.

As such, apparatus 356 may also include a compressor 344 to provide for the movement of the first fluid, such as a refrigerant, according to some embodiments. In some embodiments, a throttling device 355 may be employed to maintain pressure at a proper level, and an evaporator-style cold plate 354 may be placed into contact with one or more components for cooling.

FIG. 4 is a cross-sectional diagram of a system 400, such as, but not limited to, a computer system, with a cooling apparatus 300, according to some embodiments of the invention. In FIG. 4, the apparatus 300 may be implemented within the system 400. The system 400 may include an electronic component 416, described above, and shown here. The system 400 includes a frame (or chassis) 418 to contain the apparatus 300, the electronic component 416, and one or more air flow vents 420. In some embodiments, the air flow vents 420 are situated with respect to the apparatus 300 to provide for the intake and outtake of air, as one of ordinary skill in the relevant art would appreciate based at least on the teachings described herein.

When heat is generated by the electronic component 416, according to some embodiments of the invention, the heat may be transferred from the electronic component 416 to the cold plate 314. In some embodiments of the invention, the electronic component 416 may be directly attached to the surface of the cold plate 314. Preferably, in some embodiments of the invention, a thin highly conductive interface film material (not shown) is interposed between the electronic component 416 and the cold plate 314. This interface film material may be thermally conductive grease similar to, for example, Chomerics® T710 and Chomerics® T454 or some other substance which one of ordinary skill in the relevant art would appreciate based at least on the teachings described herein.

In some embodiments of the invention, the cold plate 314, which may include a manifold plate used with the cold plate, may include one or more microchannels, bumps, dimples, and/or posts, as one of ordinary skill in the relevant art would appreciate based at least on the teachings provided herein.

According to some embodiments of the invention, the electronic component 416 may be a processor, where the processor may include one or more cores, or a chipset. In some embodiments of the invention, the electronic component 416 may be a silicon die, of any configuration, which is employed to perform operations and as a result or by-product of operating generates heat, and may be thus considered a heat generating component even though the primary purpose of the electronic component is not to generate heat.

In some embodiments of the invention, the components of the apparatus 300 may serve to cool the electronic components 416, which may be relatively hot during operation. In some embodiments of the invention, the electronic component 416 may be processors in a computer system with power dissipation, which requires a cooling solution. Without proper cooling, the electronic components 416 may break or cease function correctly.

Although only electronic component 416 is shown in FIG. 4, the frame or chassis 418 may include more than one electronic component, and may also be used to cool other type of devices or components that generate heat. For example, components of the frame 418 may be configured for dissipating heat from a hard disk unit or a power source used in an electronic apparatus. The frame 418 may also be used to dissipate heat from an integrated circuit package or the surface of a printed circuit board. Moreover, in some embodiments of the invention, the components of the frame 418, including the apparatus 300, may have surfaces contacting one another.

As described elsewhere herein, in some embodiments of the invention, a heat pipe (not shown) may be used either with or instead of the tubing 302, and may be of the type to provide ambient flow of thermal energy.

In alternative embodiments of the invention, the system 400 may include a plurality of components, including a plurality of electronic components 416, and more than one apparatus 300, each on a respective unit or combination of units. Furthermore, the system 400 may include a plurality of heat pipes, each for a respective cold plate 314, according to some embodiments of the invention. The use of heat pipes may allow for increases in the thermal design power (TDP) of the system 400, specifically at the electronic component 416. The system 400, therefore, may be afforded an decrease in overall power requirements as the pump 304, which requires power, will not have to operate as frequently as pump 108 in system 400 or in the apparatus 300 because the heat pipe (not shown) may provide an ambient or passive pathway for thermal energy to flow from the electronic component 416 to the heat exchanger 306.

It is noted that according to some embodiments of the invention, the electronic component 416, such as, but not limited to, a microprocessor, a processor with one or more cores, a hard drive, a circuit board, or more than one electronic component. It is also noted that according to one embodiment of the invention, the electronic component 416 does not always operate at its TDP. In certain circumstances, for example, when in a power conservation mode, the electronic component 416 may operate at power levels much lower than the TDP, such as, but not limited to, 10-15 watts (W) or some other fraction of TDP. According to some embodiments of the invention, such as, but not limited to low power conditions, the embodiments of the invention may be capable of optimizing the dissipation the thermal energy generated by the electronic component 416 when operating at the fractional TDP.

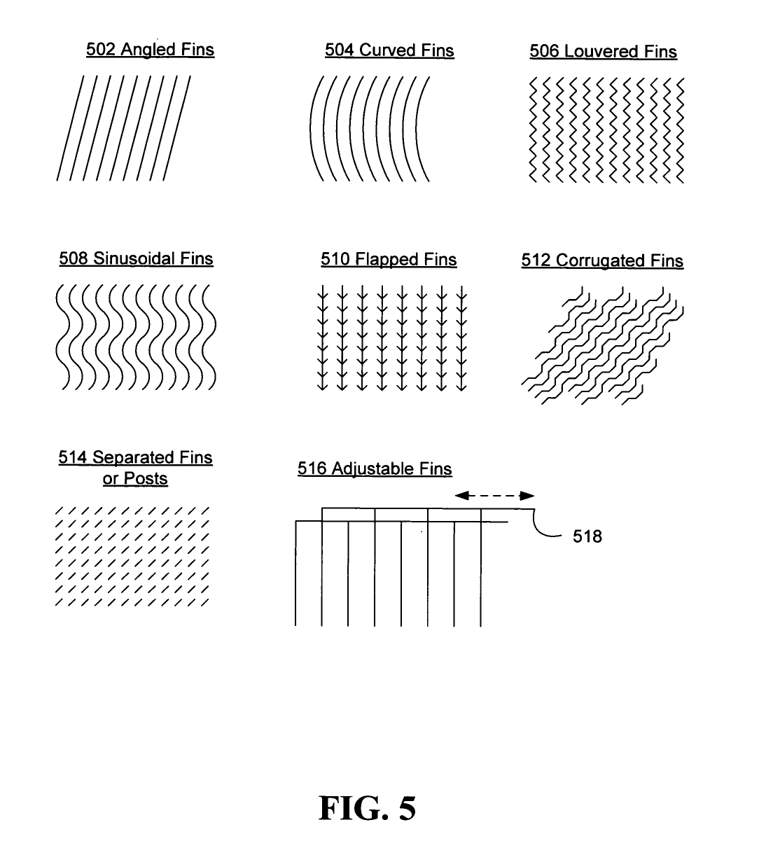

FIG. 5 includes cross-sectional diagrams of various examples of heat exchanger fin shapes according to some embodiments of the invention. As described elsewhere herein, with respect to some embodiments, the fins may be of various configurations. In some embodiments, these configurations and the fins themselves may be adjustable.

As shown in FIG. 5, angled fins 502 may be at an acute angle with respect to the airflow from the blower, according to some embodiments. In some embodiments, curved fins 504 may be used. Furthermore, in some embodiments, louvered fins 506 may be used.

Sinusoidal fins 508, flapped fins 510, and corrugated fins 512 may also be used, in some embodiments of the invention. Separated fins or posts 514 may also be used, in some embodiments, with adjustments to the spacing and configuration of some of the fins resulting in changes to the airflow which can be used to provide a uniform profile.

In addition, other fin shapes are possible and equivalent shapes or geometries may be used in accordance with some embodiments of the invention, as one of ordinary skill in the relevant art would appreciate based at least on the teachings provided herein.

According to some embodiments of the invention, combinations of one or more types of fins may be used with the heat exchanger(s) of the invention. Moreover, one or more fins of the plurality of fins, that is, a subset of the total number of fins, may be altered or adjusted as shown in one example at 516, to provide the changes in the profile necessary to make the profile uniform, in some embodiments. The adjustments, in some embodiments, are not limited to those shown in 516, and may use one or more of the types of fins described herein, as one of ordinary skill in the relevant art would appreciate based at least on the teachings described herein.

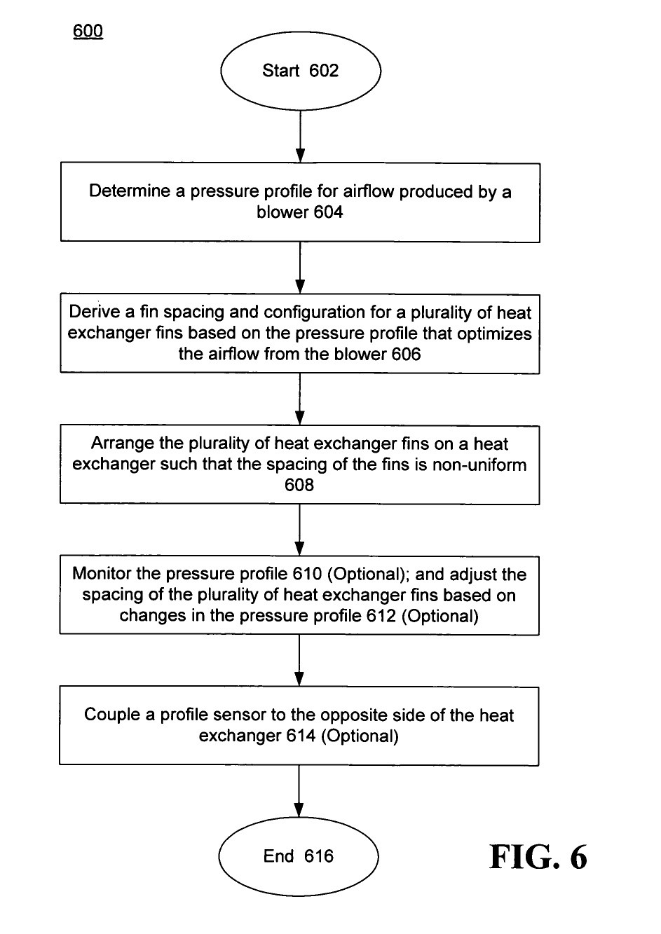

FIG. 6 shows a flow diagram of the optimized heat exchanger fin spacing process 600 according to some embodiments of the invention. In some embodiments, the process 600 may use the components and apparatus described above to perform the process. As such, in some embodiments, the process for the optimization of the profile may begin at start 602 and proceed to 604, where the process may determine a pressure profile for airflow produced by a blower.

After 604, the process 600 may then proceed to 606, where it may derive a fin spacing and configuration for a plurality of heat exchanger fins based on the pressure profile that optimizes the airflow from the blower. In some embodiments, logic of the system 400 or the apparatus 300 may perform the operations of the process. As described elsewhere herein, the logic is not shown, but may be implemented in a circuit located with in the apparatus or the system, or it may be external to the system and apparatus and used to predetermine the fin spacing and configuration based on the profile of the blower and the properties of the heat exchanger, according to some embodiments of the invention.

After 606, the process 600 may then proceed to 608, where it may arrange the plurality of heat exchanger fins on a heat exchanger such that the spacing of the fins is non-uniform. The process 600 may then proceed to end 616, where the process may terminate. The process 600 may be free to perform any of the operations 604, 606, and/or 608, as well as continue on and perform one or more optional operations described below, according to some embodiments.

In some embodiments, the process may perform the optional operation at 610 of monitoring the pressure profile, such as by the use of a profile sensor. In some embodiments, if the sensor determines that the profile is non-uniform, then the process may proceed to 612, where it may make adjustments to the spacing of the plurality of heat exchanger fins based on changes monitored in the pressure profile. The process may then have proceeded to the optional operation, in some embodiments, at 614, where the profile sensor is coupled to the opposite side of the heat exchanger. In alternative embodiments, the profile sensor may be present only temporarily to determine the uniformity of the profile and removed once adjustments have been made to the heat exchanger fins.

Embodiments of the invention may be described in sufficient detail to enable those skilled in the art to practice the invention. Other embodiments may be utilized, and structural, logical, and intellectual changes may be made without departing from the scope of the present invention. Moreover, it is to be understood that various embodiments of the invention, although different, are not necessarily mutually exclusive. For example, a particular feature, structure, or characteristic described in one embodiment may be included within other embodiments. Those skilled in the art can appreciate from the foregoing description that the techniques of the embodiments of the invention can be implemented in a variety of forms. Therefore, while the embodiments of this invention have been described in connection with particular examples thereof, the true scope of the embodiments of the invention should not be so limited since other modifications will become apparent to the skilled practitioner upon a study of the drawings, specification, and following claims.

1. A heat exchanger comprising:
a tube to transport a cooling fluid; and
a plurality of fins coupled to the tube and having a non-uniform spacing that facilitates optimizing the airflow from a blower.

2. The heat exchanger of claim 1, wherein the spacing of the plurality of fins is derived from a pressure or velocity profile produced by the blower.

3. The heat exchanger of claim 2, wherein the pressure profile is determined with respect to a distance of each fin from a central plane of the blower.

4. The heat exchanger of claim 1, wherein direction of the plates is determined by velocity of the airflow coming out of the blower.

5. The heat exchanger of claim 4, wherein shapes of the plates are angled, curved, louvered, sinusoidal, flapped, corrugated, separated posts or a combination of one or more of the shapes.

6. The heat exchanger of claim 5, wherein the heat exchanger is a condenser.

7. An apparatus comprising:
a heat exchanger including a tube to transport a cooling fluid, and a plurality of fins coupled to the tube and having a non-uniform spacing that facilitates optimizing the airflow from a blower; and
a cold plate coupled to the tube and coupled to an electronic component from which thermal energy is transferred.

8. The apparatus of claim 7, further comprising:
a pump coupled to the tube, wherein the pump circulates a cooling fluid through the tube between the cold plate and the heat exchanger.

9. The apparatus of claim 7, wherein the spacing of the plurality of fins is derived from a pressure profile produced by the blower.

10. The apparatus of claim 9, wherein direction of the plates is determined by velocity of the airflow coming out of the blower.

11. The apparatus of claim 7, wherein the plurality of fins is arranged in a stack of mutually parallel, closely-spaced plates.

12. The apparatus of claim 11, wherein shapes of the plates are angled, curved, louvered, sinusoidal, flapped, corrugated, separated posts or a combination of one or more of the shapes.

13. The apparatus of claim 12, wherein the heat exchanger is a condenser.

14. A system comprising:
a frame including airflow vents;
a plurality of components capable of generating heat, the components mounted within the chassis; and
an apparatus including a heat exchanger including a tube to transport a cooling fluid, and a plurality of fins coupled to the tube and having a non-uniform spacing that facilitates optimizing the airflow from a blower; and a cold plate coupled to the tube and coupled to an electronic component from which thermal energy is transferred.

15. The system of claim 14, further comprising:
a pump coupled to the tube, wherein the pump circulates a cooling fluid through the tube between the cold plate and the heat exchanger.

16. The system of claim 14, wherein the spacing of the plurality of fins is derived from a pressure profile produced by the blower.

17. The system of claim 16, wherein direction of the plates is determined by velocity of the airflow coming out of the blower.

18. The system of claim 14, wherein the plurality of fins is arranged in a stack of mutually parallel, closely-spaced plates.

19. The system of claim 18, wherein shapes of the plates are angled, curved, louvered, sinusoidal, flapped, corrugated, separated posts or a combination of one or more of the shapes.

20. The system of claim 19, wherein the heat exchanger is a condenser-style heat exchanger.

21. A method comprising:
determining a pressure profile for airflow produced by a blower;
deriving a fin spacing and configuration for a plurality of heat exchanger fins based on the pressure profile that optimizes the airflow from the blower; and
arranging the plurality of heat exchanger fins on a heat exchanger such that the spacing of the fins is non-uniform.

22. The method of claim 21 further comprising:
monitoring the pressure profile.

23. The method of claim 22, further comprising:
adjusting the spacing of the plurality of heat exchanger fins based on changes monitored in the pressure profile.

24. The method of claim 21 further comprising:
coupling a profile sensor to the opposite side of the heat exchanger.

25. The system of claim 14, wherein the frame is a mobile computer, a desktop computer, a server computer, or a handheld computer.
